(19) United States
(12) Patent Application Publication
(10) Pub. No.: US 2025/0132293 A1
(43) Pub. Date: Apr. 24, 2025

(54) HYBRID HIGH BANDWIDTH MEMORY STACK

(71) Applicant: International Business Machines Corporation, Armok, NY (US)

(72) Inventors: Ruilong Xie, Niskayuna, NY (US); Tao Li, Slingerlands, NY (US); Joshua M. Rubin, Albany, NY (US); Cheng Chi, Jersey City, NJ (US)

(21) Appl. No.: 18/382,471

(22) Filed: Oct. 20, 2023

(51) Int. Cl. H01L 25/065; H01L 21/768; H01L 23/522; H01L 23/528; H10B 12/00

(52) U.S. Cl. CPC H01L 25/0657; H01L 21/76898; H01L 23/5226; H01L 23/5283; H10B 12/038; H10B 12/37; H01L 2225/06513

(57) ABSTRACT

A memory device and formation thereof. The memory device includes a stack of memory dies. Each memory die in the stack of memory dies includes two or more layers of memory devices.

### BACKGROUND OF THE INVENTION

The present invention relates generally to the field of memory devices, and more particularly to high bandwidth memory stacks having memory dies with multiple layers of memory devices.

High bandwidth memory (HBM) is an emerging type of computer memory that is designed to provide both high-bandwidth and low power consumption. HBM is typically arranged in an HBM stack, in which a plurality of memory dies (e.g., dynamic random-access memory (DRAM) dies) are stacked vertically on top of a single logical die. The HBM stack may be utilized to provide a large amount of computer or system memory in a single package. The package may also include additional components, such as a memory controller, a central processing unit (CPU), or a graphics processing unit (GPU) that are interconnected to the HBM stack by an interposer₃

### SUMMARY

According to one embodiment of the present invention, a memory device is provided. The memory device includes a stack of memory dies. Each memory die in the stack of memory dies includes two or more layers of memory devices.

According to another embodiment of the present invention, a memory die is provided. The memory die includes a first layer of memory devices arranged on top of a semiconductor substrate. The memory die further includes a back-end-of-the-line (BEOL) interconnect structure arranged on top of the first layer of memory devices. The memory die further includes a second layer of memory devices arranged on top of the BEOL interconnect structure. The memory die further includes a backside interconnect structure arranged on top of the BEOL interconnect structure.

According to another embodiment of the present invention, a method of forming a memory device is provided. The method includes forming a first memory wafer structure. The first memory wafer structure includes a first semiconductor substrate, a first layer of memory devices formed on top of the first semiconductor structure, and a first back-end-of-the-line (BEOL) interconnect structure formed on top of the first layer of memory devices. The method further includes forming a second memory wafer structure. The second memory wafer structure includes a second semiconductor substrate, a second layer of memory devices formed on top of the second semiconductor structure, and a second BEOL interconnect structure formed on top of the second layer of memory devices. The method further includes directly bonding the second BEOL interconnect structure of the second memory wafer structure to the first BEOL interconnect structure of the first memory wafer structure through hybrid bonding to form a combined memory wafer structure. The method further includes removing the second semiconductor substrate from the combined memory wafer structure to reveal the second layer of memory devices. The method further includes forming a backside interconnect structure on top of the second layer of memory devices. The method further includes performing wafer dicing to separate respective memory dies from the combined memory wafer structure. Each respective memory die separated from the combined memory wafer structure includes two layers of memory devices.

### BRIEF DESCRIPTION OF THE SEVERAL VIEWS OF THE DRAWINGS

The drawings included in the present disclosure are incorporated into, and form part of, the specification. They illustrate embodiments of the present disclosure and, along with the description, serve to explain the principles of the disclosure. The drawings are only illustrative of typical embodiments and do not limit the disclosure.

The drawings are not necessarily to scale. The drawings are merely schematic representations, not intended to portray specific parameters of the invention. The drawings are intended to depict only typical embodiments of the invention. In the drawings, like numbering represents like elements.

FIG. 1 illustrates a cross-sectional view of a memory wafer structure, generally designated 100, in accordance with at least one embodiment of the present invention.

FIG. 2 illustrates a cross-sectional view of a memory wafer structure, generally designated 200, in accordance with at least one embodiment of the present invention.

FIG. 3 illustrates a cross-sectional view of an alternative version of memory wafer structure 100 of FIG. 1, generally designated 300, in accordance with at least one embodiment of the present invention.

FIG. 4 illustrates a cross-sectional view of a memory wafer structure formed as a result of bonding memory wafer structure 200 of FIG. 2 to memory wafer structure 100 of FIG. 1 through hybrid bonding, generally designated 400, in accordance with at least one embodiment of the present invention.

FIG. 5 illustrates a cross-sectional view of a memory wafer structure formed as a result of bonding memory wafer structure 200 of FIG. 2 to memory wafer structure 300 of FIG. 3 through hybrid bonding, generally designated 500, in accordance with at least one embodiment of the present invention.

FIG. 6 illustrates a cross-sectional view of memory wafer structure 400 of FIG. 4 after performing subsequent processing steps, generally designated 600, in accordance with at least one embodiment of the present invention.

FIG. 7 illustrates a cross-sectional view of memory wafer structure 500 of FIG. 5 after performing subsequent processing steps, generally designated 700, in accordance with at least one embodiment of the present invention.

FIG. 8 illustrates a cross-sectional view of memory wafer structure 600 of FIG. 6 after performing subsequent processing steps, generally designated 800, in accordance with at least one embodiment of the present invention.

FIG. 9 illustrates a cross-sectional view of memory wafer structure 500 of FIG. 7 after performing subsequent processing steps, generally designated 900, in accordance with at least one embodiment of the present invention.

FIG. 10 illustrates a cross-sectional view of a memory device, generally designated 1000, in accordance with at least one embodiment of the present invention.

FIG. 11 illustrates a cross-sectional view of memory device, generally designated 1100, in accordance with at least one embodiment of the present invention.

### DETAILED DESCRIPTION

High bandwidth memory (HBM) uses 3D stacking technology, which enables multiple layers of memory dies to be stacked on top of one another and interconnected by through-silicon vias (TSVs). This ultimately reduces footprint while also reducing the distance that data needs to travel between the memory and processor. However, embodiments of the present invention recognize that as integrated circuits move to smaller technology nodes, the ability to find ways to increase performance without an increase in package size remains challenging. For example, although vertically stacking memory dies reduces footprint and results in high yields due to the ability to individually select good dies for stacking, a tradeoff exists between the number of vertically stacked memory dies and the package height since the substrate of each memory die is relatively thick.

Embodiments of the present invention provide for an HBM device with increased performance without sacrificing package yield rates or increasing package height. This is accomplished by forming memory dies having at least two layers of memory devices without an increase in the overall package height of the memory dies. Thus, when these memory dies having at least two layers of memory devices are arranged as a memory stack, the overall memory density of the memory stack is at least doubled as compared to memory stacks of comparable height.

According to one embodiment of the present invention, a memory device is provided. The memory device includes a stack of memory dies. Each memory die in the stack of memory dies includes two or more layers of memory devices. This results in a technical advantage of doubling the memory density of the stack of memory dies, while the overall package height of the memory device remains comparable to conventional high bandwidth memory stacks.

In an embodiment, a first layer of memory devices and a second layer of memory devices included in each memory die in the stack of memory dies are the same. This results in a technical advantage of doubling the memory density for a particular type of memory in each memory die.

In an embodiment, first layer of memory devices and a second layer of memory devices included in each memory die in the stack of memory dies are different. This results in a technical advantage of multiple different memory performance characteristics being included in a single die.

In an embodiment, each memory die in the stack of memory dies is formed by hybrid bonding of a first BEOL interconnect structure of a first memory wafer to a second BEOL interconnect structure of a second memory wafer.

In an embodiment, each memory die in the stack of memory dies includes: a first layer of memory devices located below a semiconductor substrate, a second layer of memory devices located between the first layer of memory devices and a back-end-of-the-line (BEOL) interconnect structure, and a backside interconnect structure located below the second layer of memory devices. This results in a technical advantage of doubling the memory density in each memory die.

In an embodiment, the BEOL interconnect structure of each memory die is formed by hybrid bonding a first BEOL interconnect structure of a first memory wafer to a second BEOL interconnect structure of a second memory wafer. This results in a technical effect of bonding a first memory wafer to a second memory wafer.

In an embodiment, a metal layer of the BEOL interconnect structure having metal lines with a largest pitch is located in the middle of the BEOL interconnect structure.

In an embodiment, each memory die further includes one or more through-silicon-vias (TSVs). The one or more TSVs are formed within, and extend through, the semiconductor substrate, the first layer of memory devices, the BEOL interconnect structure, the second layer of memory devices, and the backside interconnect structure. This results in a technical effect of power and/or signal routing between each memory die in the stack of memory dies.

In an embodiment, each memory dies further includes one or more through-silicon-vias (TSVs). The one or more TSVs are formed within, and extend through, the semiconductor substrate, the first layer of memory devices, and a top portion of the BEOL interconnect structure. This results in a technical effect of power and/or signal routing between each memory die in the stack of memory dies.

In an embodiment, each memory die in the stack of memory dies further includes one or more deep trench capacitors formed within the semiconductor substrate. This results in a technical effect of the memory devices having lower parasitic inductances and lower thermal impedance as compared to capacitors formed in the BEOL structure of the memory dies.

In an embodiment, the stack of memory dies are vertically stacked on top of a logic die. This results in a technical effect of facilitating access to/from the stack of memory dies.

In an embodiment, the logic die is connected to at least one of an interposer or a package substrate. This results in a technical effect of facilitating access to/from additional components a memory stack package, such as a memory controller, a central processing unit (CPU), or a graphics processing unit (GPU).

According to another embodiment of the present invention, a memory die is provided. The memory die includes: a first layer of memory devices formed on top of a semiconductor substrate, a back-end-of-the-line (BEOL) interconnect structure formed on top of the first layer of memory devices, a second layer of memory devices formed on top of the BEOL interconnect structure, and a backside interconnect structure formed on top of the second layer of memory devices. This results in a technical advantage of doubling the memory density of a memory die, while the overall height of the memory die remains comparable to the height of conventional memory dies.

In an embodiment, the memory die includes one or more through-silicon-vias (TSVs). The TSVs are formed within, and extend through, the semiconductor substrate, the first layer of memory devices, the BEOL interconnect structure, the second layer of memory devices, and the backside interconnect structure. This results in a technical effect of power and/or signal routing between the memory die and another memory die vertically stacked on top of the memory die.

In an embodiment, the memory die includes one or more through-silicon-vias (TSVs). The TSVs are formed within, and extend through, the semiconductor substrate, the first layer of memory devices, and a bottom portion of the BEOL interconnect structure. This results in a technical effect of power and/or signal routing between the memory die and another memory die vertically stacked on top of the memory die.

In yet another embodiment of the present invention, a method of forming a memory die having at least two layers of memory devices is provided. The method includes forming a first memory wafer structure. The first memory wafer structure includes a first semiconductor substrate, a first layer of memory devices formed on top of the first semiconductor structure, and a first back-end-of-the-line (BEOL) interconnect structure formed on top of the first layer of memory devices.

In an embodiment, the method includes forming a second memory wafer structure. The second memory wafer structure includes a second semiconductor substrate, a second layer of memory devices formed on top of the second semiconductor structure, and a second BEOL interconnect structure formed on top of the second layer of memory devices.

In an embodiment, the method includes combining the first memory wafer structure and the second memory wafer structure to form a combined memory wafer structure. The first and second memory wafer structures are combined by flipping over the second memory wafer structure and hybrid bonding the second BEOL interconnect structure of the second memory wafer structure to the first BEOL interconnect structure of the first memory wafer structure.

In an embodiment, the method includes removing the second semiconductor substrate from the combined memory wafer structure to reveal the second layer of memory devices.

In an embodiment, the method includes forming a backside interconnect structure on top of the second layer of memory devices.

In an embodiment, the method includes performing wafer dicing to separate respective memory dies from the combined memory wafer structure. Each respective memory die separated from the combined memory wafer structure includes two or more layers of memory devices.

As a result, illustrative embodiments of the method result in a technical advantage of doubling the memory density of a memory die, while the overall height of the memory dies remains comparable to conventional high bandwidth memory dies. This also results in a technical effect of relatively good die yields since only two memory wafer structures are required to be bonded to form the combined memory wafer structure having at least two or more layers of memory devices.

In an embodiment, the method includes forming, prior to combining the first memory wafer structure and the second memory wafer structure, one or more deep trench capacitors within the first semiconductor substrate of the first memory wafer structure. This results in a technical effect of the memory devices having lower parasitic inductances and lower thermal impedance as compared to capacitors formed in the BEOL structure of the memory dies.

In an embodiment, the method includes forming, prior to combining the first memory wafer structure and the second memory wafer structure, one or more through-silicon-vias (TSVs). The TSVs are formed within, and extend through, at least a portion of the first BEOL interconnect structure and the first semiconductor structure of the first memory wafer structure. This results in a technical effect of power and/or signal routing between the memory die and another memory die vertically stacked on top of the memory die.

In an embodiment, the method includes forming, after combining the first memory wafer structure and the second memory wafer structure, one or more through-silicon-vias (TSVs). The TSVs are formed within, and extend through, the backside interconnect structure, the second layer of memory devices, the second BEOL interconnect structure, the first BEOL interconnect structure, the first layer of memory devices, and the first semiconductor substrate. This results in a technical effect of power and/or signal routing between the memory die and another memory die vertically stacked on top of the memory die.

In an embodiment, the method includes vertically stacking two or more respective memory dies separated from the combined memory structure on top of a logic die. This results in a technical effect of facilitating access to/from the stack of memory dies. This also results in a technical advantage of doubling the memory density of the stack of memory dies, while the overall package height of the memory device remains comparable to conventional high bandwidth memory stacks.

Exemplary embodiments now will be described more fully herein with reference to the accompanying drawings, in which exemplary embodiments are shown. In the following detailed description, numerous specific details are set forth in order to provide a thorough understanding of various embodiments of the invention. However, it is to be understood that embodiments of the invention may be practiced without these specific details. As such, this disclosure may be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

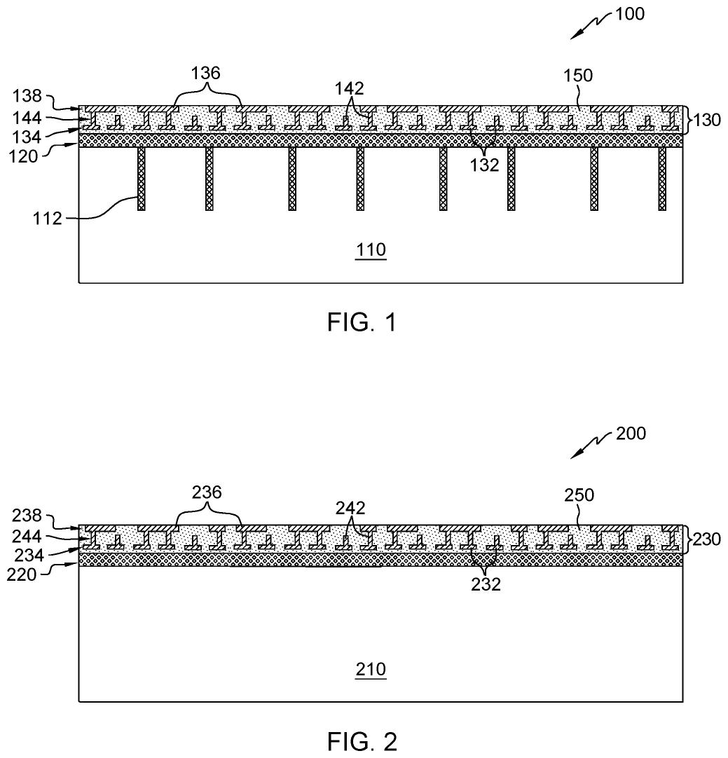

As described below, in conjunction with FIGS. 1-11, embodiments of the present invention provide for a hybrid HBM device, and methods of forming the same, in which each memory die in a stack of memory dies includes at least two layers of memory devices. The methods described below in conjunction with FIGS. 1-11 may be incorporated into typical semiconductor memory device fabrication processes. As such, when viewed as ordered combinations, FIGS. 1-11 illustrate methods for forming a hybrid HBM device having at least twice the memory density as conventional HBM devices without an increase in the overall package height.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. Terms such as “above”, “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is focused on the distinctive features or elements of various embodiments of the present invention.

As used herein, terms such as “depositing,” “forming,” and the like may refer to the disposition of layers, or portions of materials, in accordance with a given embodiment. Such processes may or may not be different than those used in the standard practice of the art of microcooler device fabrication. Such processes include, but are not limited to, atomic layer deposition (ALD), molecular layer deposition (MLD), chemical vapor deposition (CVD), low-pressure chemical vapor deposition (LPCVD), plasma enhanced chemical vapor deposition (PECVD), limited reaction processing CVD (LRPCVD), ultrahigh vacuum chemical vapor deposition (UHVCVD), metalorganic chemical vapor deposition (MOCVD), physical vapor deposition, sputtering, plating, electroplating, evaporation, ion beam deposition, electron beam deposition, laser assisted deposition, chemical solution deposition, or any combination of those methods.

As used herein, terms, such as “forming,” and the like, may refer to processes that alter the structure and/or composition of one or more layers of material or portions of materials in accordance with a given embodiment. For example, such formation processes may include, but are not limited to, exposure to a specific frequency or range of frequencies of electromagnetic radiation, ion implantation techniques, and/or chemical/mechanical polishing (CMP). As used herein, terms, such as “forming,” and the like, may refer to processes that alter the structure of one or more layers of material, or portions of material(s), by removal of a quantity of material, in accordance with a given embodiment. For example, such formation processes may include, but are not limited to, micromachining, microetching, wet and/or dry etching processes, plasma etching processes, or any of the known etching processes in which material is removed.

Those skilled in the art understand that many different techniques may be used to add, remove, and/or alter various materials, and portions thereof, and that embodiments of the present invention may leverage combinations of such processes to produce the structures disclosed herein without deviating from the scope of the present invention.

The present invention will now be described in detail with reference to the Figures. FIGS. 1-11 include various cross-sectional views depicting illustrative steps of methods for manufacturing hybrid HBM devices having at least two layers of memory devices and the resulting hybrid HBM memory devices according to select embodiments of the present invention. One having ordinary skill in the art will appreciate that there are many options available for the formation of the structures described herein and that the following discussion does not limit embodiments to only the techniques described herein.

Referring now to FIGS. 1-3, cross-sectional views of memory wafer structures 100, 200, and 300 are illustrated in accordance with at least one embodiment of the present invention. In some embodiments, and as depicted in FIGS. 1-3, each of memory wafer structures 100, 200, 300 are representative of a plurality of memory dies formed on a single semiconductor wafer. In assembly of memory wafer structures 100, 300, a layer of memory devices 120 is formed on top of a substrate 110, followed by the formation of a back-end-of-the-line (BEOL) interconnect structure 130 on top thereof. Similarly, in assembly of memory wafer structure 200, a layer of memory devices 220 is formed on top of a substrate 210, followed by the formation of a back-end-of-the-line (BEOL) interconnect structure 230 on top thereof.

In some embodiments, and as depicted in FIGS. 1-3, substrates 110, 210 are bulk semiconductor wafers, such as a bulk silicon (Si), bulk germanium (Ge), bulk silicon germanium (SiGe) and/or bulk III-V semiconductor wafer. Alternatively, in other embodiments, substrates 110, 210 are semiconductor-on-insulator (SOI) wafers. A SOI wafer includes a SOI layer separated from a substrate by a buried insulator. When the buried insulator is an oxide, it is referred to herein as a buried oxide or BOX. The SOI layer can include any suitable semiconductors, such as Si, Ge, SiGe, and/or a III-V semiconductor.

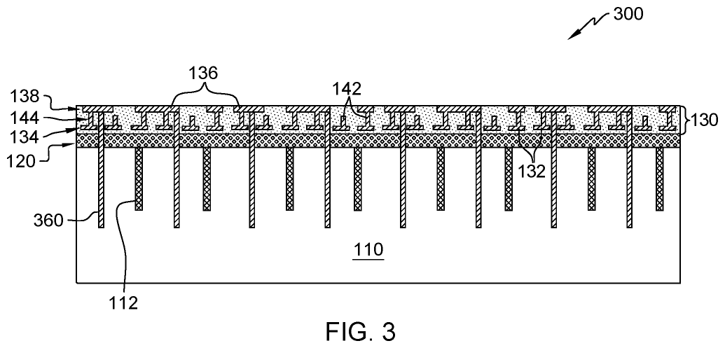

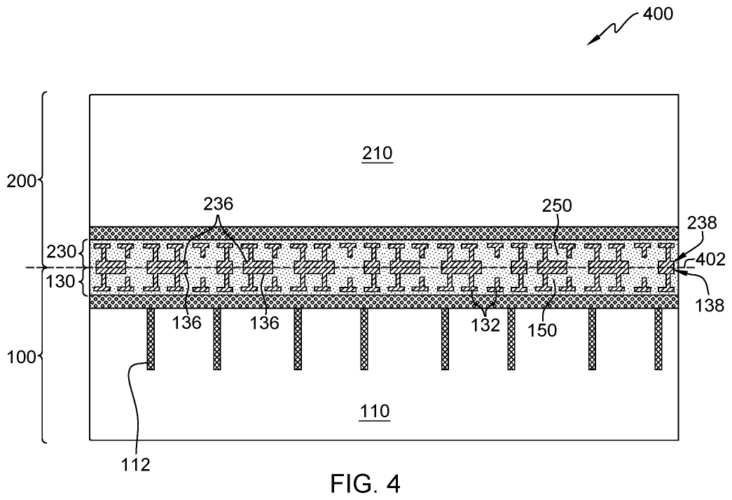

In some embodiments, and as depicted in FIGS. 1 and 3, deep trench capacitors 112 are formed within substrate 110 of memory wafer structure 100 and connected to various FEOL device components (e.g., transistors) included in layer of memory devices 120. It should be appreciated that deep trench capacitors are not formed within substrate 210 of memory wafer structure 200, since substrate 210 is later removed after bonding, for example, memory wafer structure 200 to memory wafer structure 100, as discussed in further detail below with respect to FIG. 4. As used herein, a deep trench capacitor shall mean a vertical capacitor formed, at least partially, within a deep trench of a semiconductor substrate, such as substrate 110. Deep trench capacitors 112 may be formed using one or more conventional semiconductor manufacturing processes for forming deep trench capacitors as known by one of ordinary skill in the art, and as such, a more detailed description of such processes is not presented herein. Deep trench capacitors 112 may include, but are not limited to, metal-oxide-semiconductor (MOS) capacitors, metal-insulator-metal (MIM) capacitors, metal-oxide-metal (MOM) capacitors, or any combinations thereof.

Layers of memory devices 120, 220 are formed using one or more front-end-of-the-line (FEOL) processes as known by one of ordinary skill in the art, and as such, a more detailed description of such processes is not presented herein. Layers of memory devices 120, 220 include various FEOL device components, including, but not limited to, transistors, capacitors, and resistors. In some embodiments, layer of memory devices 120 is structurally similar to layer of memory devices 220. For example, the gate length or gate pitch of the transistors in layer of memory devices 120 are the same as the gate length or gate pitch of the transistors in layer of memory devices 220, such that the performance characteristics between layers of memory devices 120, 220 are also the same. In other embodiments, layer of memory devices 120 is structurally different than layer of memory devices 220. For example, the gate length or gate pitch of the transistors in layer of memory devices 120 may be different than the gate length or gate pitch of the transistors in layer of memory devices 220, such that the performance characteristics between layers of memory devices 120, 220 are also different.

In some embodiments, and as depicted in FIGS. 1-3, layers of memory devices 120, 220 are dynamic random access memory (DRAM). However, in other embodiments, layers of memory devices 120, 220 may be any type of non-volatile or volatile memory. For example, non-volatile memory may include, but is not limited to, NAND or NOR memory, single or multi-level phase change memory (PCM), resistive memory, nanowire memory, ferroelectric transistor random access memory (FeTRAM), anti-ferroelectric memory, resistive memory including a metal oxide base, an oxygen vacancy base and a conductive bridge random access memory (CB-RAM), a spintronic magnetic junction memory, a magnetic tunneling junction (MTJ) memory, a domain wall (DW) and spin orbit transfer (SOT) memory, a thyristor based memory, a random access memory (RAM) a magnetoresistive random access memory (MRAM) that incorporates memristor technology, spin transfer torque MRAM (STT-MRAM), or any combination thereof.

BEOL interconnect structures 130, 230 are formed using one or more BEOL processes (e.g., single damascene process, dual damascene process, subtractive metal patterning) as known by one of ordinary skill in the art, and as such, a more detailed description of such processes is not presented herein. BEOL interconnect structures 130, 230 include multiple layers of interconnect wiring, embedded within a series of interlayer dielectric (ILD) layers, used to distribute clock and other signals, provide power and ground for various electronic system components, and interconnect the individual FEOL device components (e.g., transistors, capacitors, resistors) in layers of memory devices 120, 220, respectively. Within BEOL interconnect structures 130, 230, metal lines run parallel to substrates 110, 210, and conductive vias run perpendicular to substrates 110, 210, in which the conductive vias interconnect the different levels of metal lines. In some embodiments, BEOL interconnect structure 130 is the same as BEOL interconnect structure 230. For example, the arrangement of the metal lines and vias that form the multiple layers of interconnect wiring of BEOL interconnect structures 130, 230 are similar. In other embodiments, BEOL structure 130 is different than BEOL 230. For example, the arrangement of the metal lines and vias that form the multiple layers of interconnect wiring of BEOL structures 130, 230 is different.

As depicted in FIGS. 1 and 3, BEOL interconnect structure 130 includes metal lines 132 of a first metal layer 134, metal lines 136 of a second metal layer 138, and vias 142 of a first via layer 144 formed within a series of layers of an interlayer dielectric (ILD) material 150, in which at least a portion of first vias 142 interconnect metal lines 132 with respective metal lines 136. Similarly, and as depicted in FIG. 2, BEOL interconnect structure 230 includes metal lines 232 of a first metal layer 234, metal lines 236 of a second metal layer 238, and vias 242 of a first via layer 244 formed within a series of layers of an interlayer dielectric (ILD) material 250, in which at least a portion of vias 142 interconnect metal lines 132 with respective metal lines 136. It should be appreciated that only two metal layers and one via layer are depicted for illustration purposes only, and that BEOL interconnect structures 130, 230 may include any number of metal layers and via layers. It should further be appreciated that metal lines 132, 232 are depicted for illustration purposes only, and that at least a portion of metal lines 132, 232 may be connected to the various FEOL device components included in layers of memory devices 120, 220.

The respective metal lines and vias included in BEOL interconnects structures 130, 230 may be composed of a metal barrier layer (e.g., tantalum (Ta), tantalum nitride (TaN), titanium nitride (TiN), hafnium nitride (HfN), cobalt (Co), ruthenium (Ru), tungsten (W), tungsten nitride (WN), titanium-tungsten (TiW), tungsten nitride (WN) manganese (Mn), manganese nitride (MnN) or other barrier materials (or combinations of barrier materials) such as RuTaN, Ta/TaN, CoWP, NiMoP, or NiMoB which are suitable for the given application), an optional plating seed layer (e.g., Cu, a Cu alloy, Ir, an Ir alloy, Ru, a Ru alloy (e.g., TaRu alloy) or any other suitable noble metal or noble metal alloy having a low metal-plating overpotential) formed over the metal barrier layer to selectively promote subsequent electroplating, followed by a conductive metal fill (e.g., a metal or metal alloy including, but not limited to, copper (Cu), aluminum (Al), ruthenium (Ru), rhodium (Rh), iridium (Ir), tungsten (W), molybdenum (Mo), nickel (Ni), or an alloy thereof, such as, for example, a Cu—Al alloy).

ILD materials 150, 250 may be an inorganic dielectric material or an organic dielectric material. In some embodiments, ILD materials 150, 250 may be porous. In other embodiments, ILD materials 150, 250 may be non-porous. In some embodiments, ILD materials 150, 250 may have a dielectric constant (all dielectric constants mentioned herein are measured relative to a vacuum, unless otherwise stated) that is about 4.0 or less. In an embodiment, ILD materials 150, 250 may have a dielectric constant of 2.8 or less. These dielectrics having a dielectric constant of 2.8 or less generally have a lower parasitic cross talk as compared to dielectric materials whose dielectric constant is greater than 4.0. Examples of suitable dielectric materials 150, 250 include, but are limited to, porous silicates, silicon dioxides, silicon oxynitrides, silicon carbides, silicon nitrides, silicon undoped or doped silicate glass, silsesquioxanes, carbon doped oxides (i.e., organosilicates) that include atoms of Si, C, O and H, and variants thereof, siloxanes, thermosetting polyarylene ethers or any multilayered combination thereof. The term “polyarylene” is used in this present application to denote aryl moieties or inertly substituted aryl moieties which are linked together by bonds, fused rings, or inert linking groups such as, for example, oxygen, sulfur, sulfone, sulfoxide, or carbonyl.

In some embodiments, BEOL interconnect structures 130, 230 further include various BEOL device components (e.g., BEOL MIM capacitors, BEOL MOM capacitors, BEOL transistors) integrated with the different levels of metal wiring. In those embodiments in which a wafer (e.g., substrate 110) includes deep trench capacitors (e.g. deep trench capacitors 112), BEOL structure 130 may optionally include BEOL capacitors in addition to the deep trench capacitors.

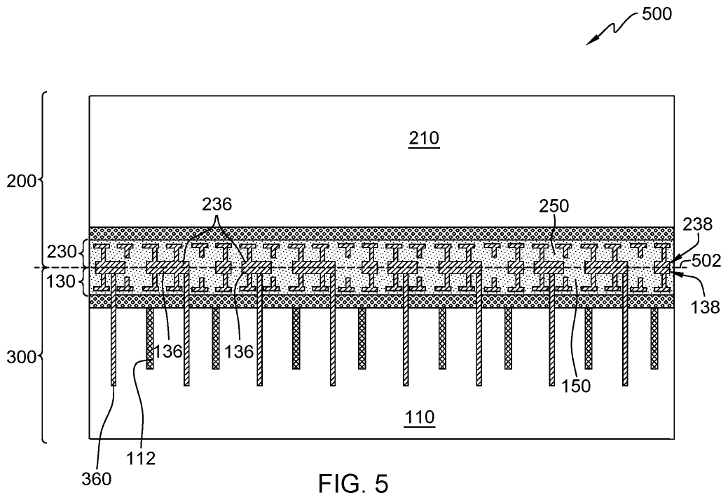

Referring now to FIG. 3, a cross-sectional view of an alternative version of semiconductor structure 100 of FIG. 1, generally designated 300, is depicted in accordance with at least one embodiment of the present invention. It should be noted that memory wafer structure 300 of FIG. 3 is substantially similar to memory wafer structure 100 of FIG. 1, but for the addition of through silicon vias (TSVs) 360. In some embodiments, and as depicted in FIG. 3, TSVs 360 are formed at least partially within substrate 110, and prior to bonding memory wafer structure 200 of FIG. 2 to memory wafer structure 300 as discussed in further detail below with respect to FIG. 5.

As depicted in FIG. 3, TSVs 360 are connected to a bottom surface of respective metal lines 136 of second metal layer 138, and extend through BEOL interconnect structure 130, through layer of memory devices 120, and at least partially through substrate 110. It should be appreciated that although TSVs 360 are depicted as being connected to metal lines 136 of second metal layer 138, which is the topmost or highest metal layer of BEOL interconnect structure 130, TSVs 360 may be connected to any metal lines of any number of metal layers formed in BEOL interconnect structure 130.

TSVs 360 may be formed using one or more BEOL processes (e.g., single damascene process, dual damascene process, subtractive metal patterning) as known by one of ordinary skill in the art. For example, a dual damascene process to form a TSV connected to a metal line of BEOL interconnect structure 130 may be performed as follows. Using standard lithography techniques, a trench opening, followed by a via opening located below the trench opening may be formed by using an anisotropic etching process, such as, for example, reactive ion etching (RIE), ion beam etching (IBE), chemical wet etching, or a combination of IBE and chemical wet etching in combination with one or more patterned hard masks. After forming the trench and via openings, thin film deposition to provide a metal barrier layer, and optional seed layer within the trench and via openings is performed, followed by the deposition or electroplating of a conductive metal fill within the trench and via openings to form TSVs 360 and respective metal lines 136 located on top thereof. The metal barrier layer, optional seed layer, and conductive metal fill may be formed using the same materials as previously described above with reference to the materials used to form the metal lines and vias of BEOL interconnect structures 130, 230.

FIG. 4 illustrates memory wafer structure 400 formed as a result of directly bonding memory wafer structure 200 of FIG. 2 to memory wafer structure 100 of FIG. 1 through hybrid bonding, in accordance with at least one embodiment of the present invention. In assembly of the hybrid bonded memory wafer structure 400, memory wafer structure 200 is flipped over, BEOL interconnect structure 230 of memory wafer structure 200 is bonded to BEOL interconnect structure 130 of memory wafer structure 100 at the interface 402 through hybrid bonding. One of ordinary skill in the art will appreciate that hybrid bonding is a permanent bond that combines dielectric-to-dielectric bonds (e.g. between ILD materials) and metal-to-metal bonds (e.g., between metal lines embedded within the ILD materials).

For example, to achieve the hybrid bonded memory wafer structure 400, memory wafer structure 200 is first pre-bonded to memory wafer structure 100 by flipping over memory wafer structure 200, aligning metal lines 236 of second metal layer 238 of BEOL interconnect structure 230 of memory wafer structure 200 with corresponding metal lines 136 of second metal layer 138 of BEOL interconnect structure 130 of memory wafer structure 100, and lightly pressing memory wafer structure 200 against memory wafer structure 100. During this pre-bonding process, an initial, temporary dielectric-to-dielectric bond occurs at the interface 402 of ILD materials 150, 250 at room temperature under atmospheric conditions.

Subsequently, the temporary bonded memory wafer structures 100, 200 are subjected to a thermal annealing process, which causes a permanent dielectric-to-dielectric bond and metal-to-metal bond. The thermal annealing can be, for example, a furnace anneal, rapid thermal anneal, flash anneal, or laser anneal. In an embodiment, for furnace anneal and rapid thermal anneal, the annealing temperature can range from 150° C. to 450° C. for furnace anneal and rapid thermal anneal and the anneal duration can range from 10 minutes to one hour or longer. In an embodiment, for flash anneal/laser anneal, the annealing temperature can be higher (e.g., from 450° C. to 1000° C.), but the anneal duration is much shorter (e.g., ranging from 100 nanoseconds to 100 milliseconds).

As a result of the thermal annealing process, ILD material 250 of memory wafer structure 200 is bonded to ILD material 150 of memory wafer structure 100 at interface 402 through covalent bonds (i.e., a chemical bond that involves the sharing of electrons to form electron pairs between atoms). For example, the atoms (such as oxygen atoms) at the surface of ILD material 250 form covalent bonds (such as O—H bonds) with the atoms (such as hydrogen atoms) at the surface of ILD material 150. The resulting bonds between the dielectric layers are dielectric-to-dielectric bonds, which may be inorganic-to-polymer, polymer-to-polymer, or inorganic-to-inorganic bonds in accordance with various embodiments. In some embodiments. ILD materials 150, 250 at the respective surfaces of BEOL structures 130, 230 may be the same as each other (e.g., both being polymer layers). In other embodiments, ILD 150, 250 at the respective surfaces of BEOL structures 130, 230 may be different from each other (e g., one being a polymer layer and the other being an inorganic layer). Accordingly, in these embodiments, there may be two types of inorganic-to-polymer, polymer-to-polymer, and inorganic-to-inorganic bonds existing simultaneously at interface 402.

As a further result of the thermal annealing process, metal lines 236 of metal layer 238 of BEOL interconnect structure 230 are bonded to the respective metal lines 136 of metal layer 138 of BEOL interconnect structure 130 at interface 402 through the inter-diffusion of metals. In some embodiments, metal lines 136, 236 may be formed from the same conductive metal materials (e.g., both being formed from Cu). In other embodiments, metal lines 136, 236 may be formed from different conductive metal materials (e.g., one from Cu and one from Ru). Accordingly, in these embodiments, intermetallic bonds may be formed between the atoms of Cu and the atoms of Ru at interface 402.

FIG. 5 illustrates memory wafer structure 500 formed as a result of directly bonding memory wafer structure 200 of FIG. 2 to memory wafer structure 300 of FIG. 3 through hybrid bonding, in accordance with at least one embodiment of the present invention. It should be appreciated that memory wafer structure 500 of FIG. 5 is substantially similar to memory wafer structure 400 of FIG. 4, but for the presence of TSVs 360 formed within memory wafer structure 300 prior to bonding memory wafer structure 200 to memory wafer structure 300. The hybrid bonded memory wafer structure 500 formed as a result of bonding memory wafer structure 200 to memory wafer structure 300 may be achieved using the same processes as previously discussed above with respect to the formation of the hybrid bonded memory wafer structure 400 of FIG. 4, and as such, a more detailed description of such processes is not presented herein.

After temporarily bonding memory wafer structure 200 to memory wafer structure 300, and subjecting the temporarily bonded memory wafer structures 200, 300 to a thermal annealing process, ILD material 250 of memory wafer structure 200 is bonded to ILD material 150 of memory wafer structure 300 at interface 502 through covalent bonds (i.e., a chemical bond that involves the sharing of electrons to form electron pairs between atoms). Similarly, metal lines 236 of second metal layer 238 of BEOL interconnect structure 230 of memory wafer structure are bonded to the respective metal lines 136 of second metal layer 138 of BEOL interconnect structure 130 of memory wafer device 300 at interface 502 through the inter-diffusion of metals.

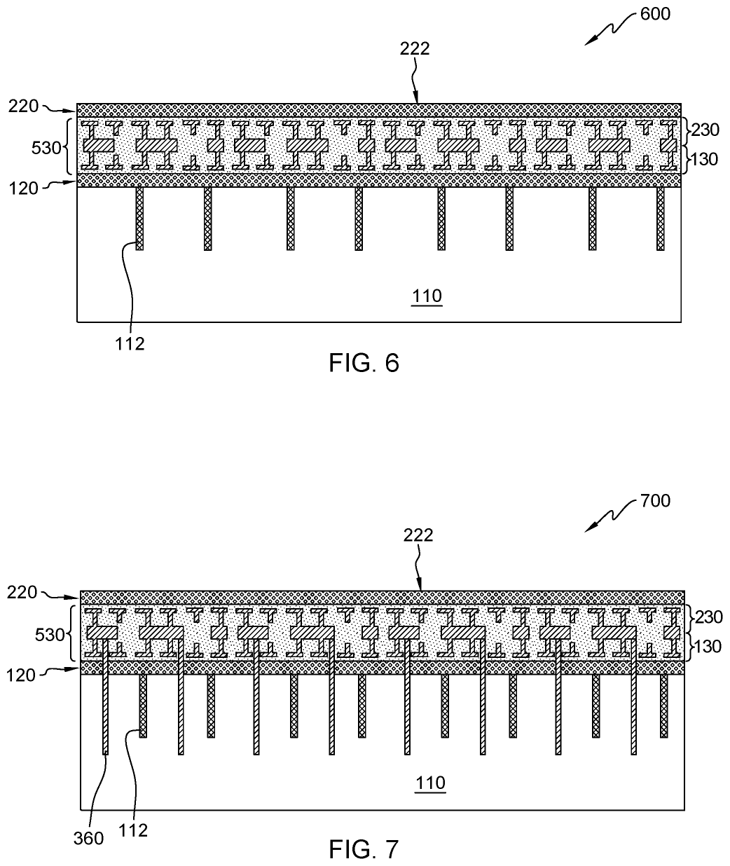

FIG. 6 illustrates a cross-sectional view of memory wafer structure 400 of FIG. 4 after performing subsequent processing steps, generally designated 600, in accordance with at least one embodiment of the present invention. After bonding memory wafer structure 200 to memory wafer structure 100 to form memory wafer structure 400 of FIG. 4, substrate 210 from memory wafer structure 200 is removed by a combination of grinding, CMP, dry etch and wet etch processes to reveal the surface 222 of layer of memory devices 220.

After removing substrate 210, the resulting hybrid bonded memory wafer structure 600 includes a single substrate (i.e., substrate 110) having two layers of memory devices (i.e., layer of memory devices 120 and layer of memory devices 220). In particular, memory wafer structure 600 includes, in order from bottom to top, substrate 110, layer of memory devices 120, BEOL interconnect structure 130, BEOL interconnect structure 230, and layer of memory devices 220. Accordingly, memory wafer structure 600 includes a first layer of memory devices (i.e., layer of memory devices 120 from memory wafer structure 100) formed on top of a substrate (i.e., substrate 110), and a second layer of memory devices (i.e., layer of memory devices 220 from memory wafer structure 200) formed above the first layer of memory devices 120. BEOL interconnect structure 130 from memory wafer structure 100 and BEOL interconnect structure 230 from memory wafer structure 200 are further located between layer of memory devices 120 and layer of memory devices 220, and are generally depicted as a single BEOL interconnect structure 530.

FIG. 7 illustrates a cross-sectional view of memory wafer structure 500 of FIG. 5 after performing subsequent processing steps, generally designated 600, in accordance with at least one embodiment of the present invention. After bonding memory wafer structure 200 to memory wafer structure 300 to form memory wafer structure 500 of FIG. 5, substrate 210 from memory wafer structure 200 is removed by a combination of grinding, CMP, dry etch and wet etch processes to reveal the surface 222 of layer of memory devices 220.

It should appreciated that memory wafer structure 700 of FIG. 7 is substantially similar to memory wafer structure 600 of FIG. 6, but for the presence of TSVs 360 formed within memory wafer structure 300 prior to bonding memory wafer structure 200 to memory wafer structure 300. Like the hybrid bonded memory wafer structure 600 of FIG. 6, after removing substrate 210 from memory wafer structure 500 (depicted in FIG. 5), the resulting hybrid bonded memory wafer structure 600 includes a single substrate (i.e., substrate 110) having two layers of memory devices (i.e., layer of memory devices 120 and layer of memory devices 220) separated by BEOL interconnect structure 530.

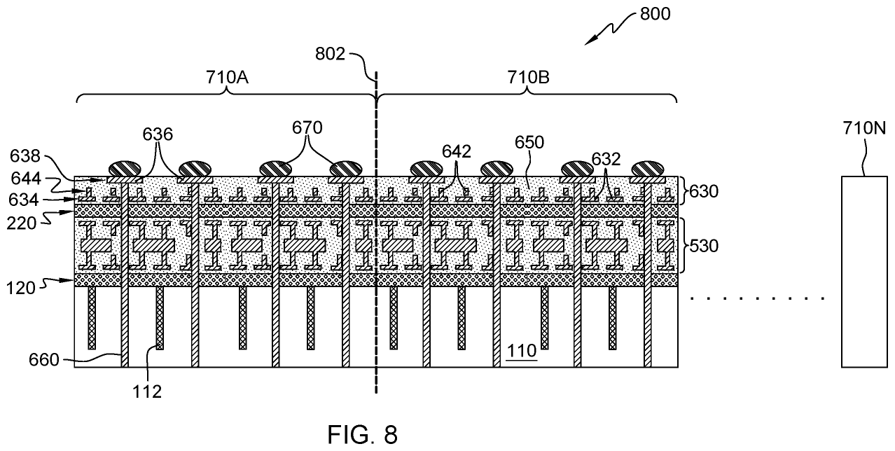

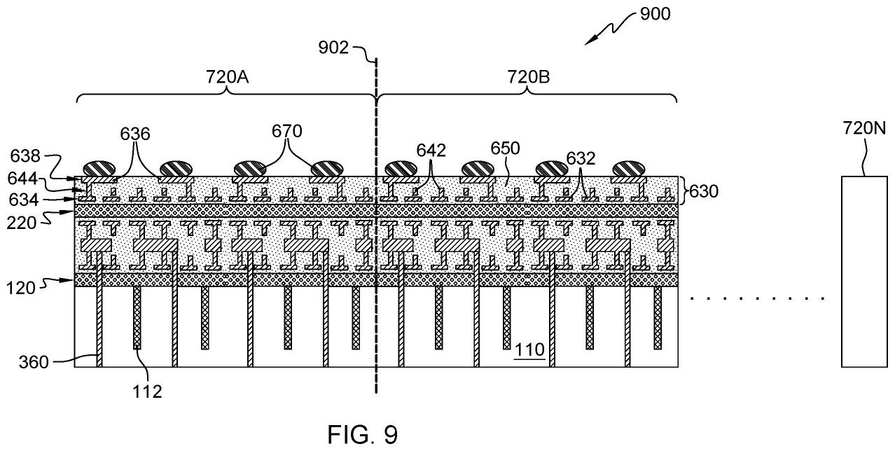

FIGS. 8-9 illustrate cross-sectional views of memory wafer structures 600, 700 depicted in FIGS. 6-7 after performing subsequent processing steps, generally designated 800, 900, in accordance with at least one embodiment of the present invention. In assembly of memory wafer structures 800, 900 a backside interconnect structure 630 is formed onto the revealed surface of layer of memory devices 220.

Backside interconnect structure 630 may be formed using one or more backside metallization processes (e.g., single damascene process, dual damascene process, subtractive metal patterning) as known by one of ordinary skill in the art and, as such, a more detailed description of such processes is not presented herein. In some embodiments, backside interconnect structure 630 is a form of backside power delivery and/or signal routing. Backside interconnect structure 630 includes multiple levels of backside wiring formed from backside metals (BSMs) and backside vias (BVs) embedded within a series of interlayer dielectric (ILD) layers. The respective backside metal lines and vias included in backside interconnect structure 630 may be formed using the same materials as previously described above with reference to the materials used to form the metal lines and vias of BEOL interconnect structures 130, 230.

As depicted in FIGS. 8-9, backside interconnect structure 630 includes backside metal lines 632 of a first backside metal layer 634, backside metal lines 636 of a second backside metal layer 638, and backside vias 642 of a first backside via layer 644 formed within a series of layers of an ILD material 650, in which at least a portion of backside vias 642 interconnect backside metal lines 632 with respective backside metal lines 636. It should be appreciated that only two backside metal layers and one backside via layer are depicted for illustration purposes only, and that backside interconnect structure 630 may include any number of backside metal layers and backside via layers. It should further be appreciated that backside metal lines 632 and backside vias 642 are depicted for illustration purposes only. For example, and referring specifically to FIG. 8, at least a portion of backside metal lines 632 may be connected to the various FEOL device components included in layer of memory devices 220.

In an embodiment, power is delivered to the FEOL devices (e.g., transistors) included in layers of memory devices 120, 220 through one or more buried power rails connected to respective backside metal lines of backside interconnect structure 630 using one or more nano TVSs (nTSVs). In an embodiment, power is delivered directly from backside interconnect structure 630 to a memory cell or transistor contact of layers of memory devices 120, 220 using one or more power vias. In an embodiment, power is delivered from backside interconnect structure 630 to one are more backside contacts connected to respective source/drain (S/D) of transistors included in layers of memory devices 120, 220. In some embodiments, backside interconnect structure 630 further includes one or more vias for signal routing. For example, one or more through-dielectric-vias (TDVs) are used to deliver signals between the backside metal wiring of backside interconnect structure 630 and layers of memory devices 120, 220.

Referring now to FIG. 8, through silicon vias (TSVs) 660 are formed within memory wafer structure 800, and are connected to backside metal lines 636 of backside interconnect structure 630. TSVs 660 extend through backside interconnect structure 630, layer of memory devices 220, BEOL interconnect structure 530, layer of memory devices 120, and at least partially through substrate 110. One of ordinary skill in the art will appreciate that TSVs 630 allow for multiple individual memory dies (e.g., formed after performing wafer dicing of memory wafer structure 800 as described in further detail below with respect to FIG. 8) to be stacked vertically for a broad range of applications and performance improvements such as increased bandwidth, reduced signal delay, improved power management, and small form factors.

TSVs 660 may be formed using one or more BEOL processes (e.g., single damascene process, dual damascene process, subtractive metal patterning) as known by one of ordinary skill in the art. For example, a dual damascene process to form a TSV 660 connected to a backside metal line 636 of backside interconnect structure 630 may be performed as follows. Using standard lithography techniques, a trench opening, followed by a via opening located below the trench opening may be formed by using an anisotropic etching process, such as, for example, reactive ion etching (RIE), ion beam etching (IBE), chemical wet etching, or a combination of IBE and chemical wet etching in combination with one or more patterned hard masks. After forming the trench and via openings, thin film deposition to provide a metal barrier layer, and optional seed layer within the trench and via openings is performed, followed by the deposition or electroplating of a conductive metal fill within the trench and via openings to form TSVs 660 and respective backside metal lines 636 located on top thereof. The metal barrier layer, optional seed layer, and conductive metal fill may be formed using the same materials as previously described above with reference to the materials used to form the metal lines 136 and TSVs 360 in FIG. 3.

After performing wafer thinning (e.g., performing a planarization process such as, for example, chemical mechanical planarization or polishing (CMP) and/or grinding) to reveal TSVs 660 formed within substrate 110, solder bumps 670 are formed on top of backside metal lines 636 formed within backside interconnect structure 630. Solder bumps 670 provide a form of interconnection between two vertically stacked hybrid bonded dies (e.g., two individual hybrid bonded dies separated from memory wafer structure 800). In an embodiment, solder bumps 670 are controlled collapse chip connections (C4s). In an alternative embodiment, solder bumps 670 are micro C4s that have a smaller diameter and finer pitch as compared to C4s.

Finally, wafer dicing is performed to separate the individual memory dies 710A . . . 710N from memory wafer structure 800 using one or more wafer dicing processes as known by one of ordinary skill in the art, including, but not limited to, wafer scribing and breaking, mechanical sawing, laser dicing, laser ablation dicing, stealth dicing, and plasma dicing (i.e., deep reactive ion etching (DRIE)). The separation of individual memory dies 710A, 710B from memory wafer structure 800 is indicated by dashed line 802. It should be appreciated that two individual memory dies 710A, 710B are depicted as being separated from memory wafer structure 800 for illustration purposes only, and that any number of memory dies 710A . . . 710N may be separated from memory wafer structure 800.

Referring now to FIG. 9, after forming backside interconnect structure 630, wafer thinning is performed to reveal TSVs 360 formed within substrate 110. It should be appreciated that unlike the hybrid bonded memory wafer structure 800 of FIG. 8, in which TSVs 660 are formed after hybrid bonding of memory wafer structure 200 to memory wafer structure 100, the hybrid bonded semiconductor structure 900 of FIG. 9 already includes TSVs 360 formed prior to hybrid bonding of memory wafer structure 200 to memory wafer structure 300. This may be advantageous in that TSVs need not be formed through the entire hybrid bonded memory wafer structure. Rather, power and/or signal routing between two stacked dies may be routed through TSVs 360, BEOL interconnect structure 530, and backside interconnect structure 630.

As further depicted in FIG. 9, solder bumps 670 are formed on top of respective backside metal lines 636 of second backside metal layer 638 formed within backside interconnect structure 630, followed by wafer dicing of memory wafer structure 900 to separate the individual memory dies 720A . . . 720N from memory wafer structure 900 using one or more wafer dicing processes as known by one of ordinary skill in the art, including, but not limited to, wafer scribing and breaking, mechanical sawing, laser dicing, laser ablation dicing, stealth dicing, and plasma dicing (i.e., deep reactive ion etching (DRIE)). The separation of individual memory dies 720A, 720B from memory wafer structure 900 is indicated by dashed line 902. It should be appreciated that two individual memory dies 720A, 720B are depicted as being separated from memory wafer structure 900 for illustration purposes only, and that any number of memory dies 720A . . . 720N may be separated from memory wafer structure 900.

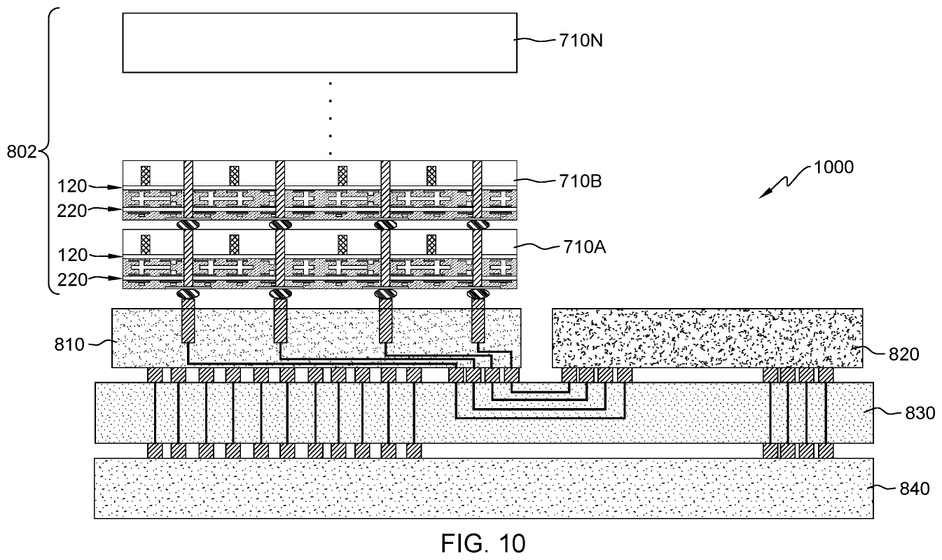

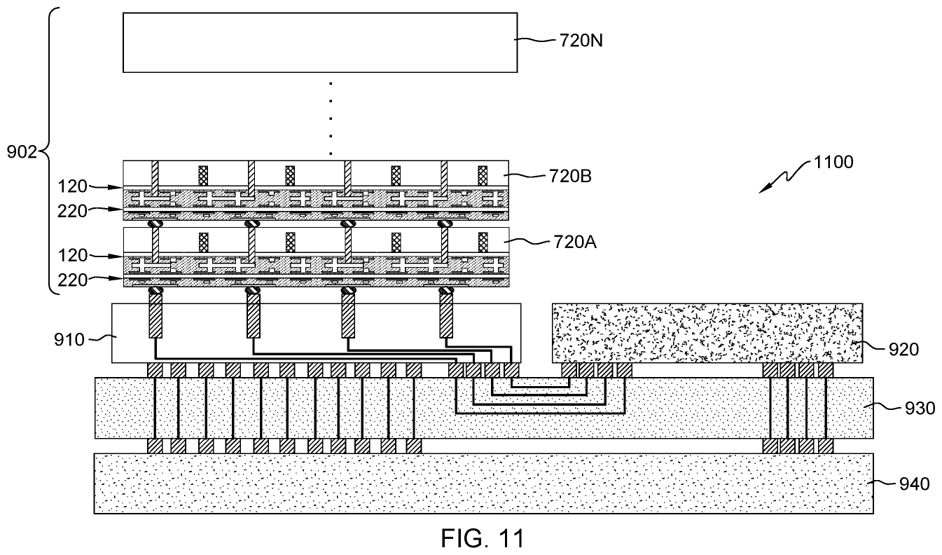

FIGS. 10-11 illustrate cross-sectional views of hybrid bonded memory devices 1000, 1100, in accordance with at least one embodiment of the present invention. Hybrid bonded memory devices 1000, 1100 include memory dies 710A, 710B and memory dies 720A, 720B stacked vertically on top of respective logic dies 810, 910. It should be appreciated that two vertically stacked memory devices (memory devices 710A, 710B of FIG. 10) and (memory devices 720A, 720B of FIG. 11) are depicted for illustration purposes only, and that depending on the particular package height requirements, any number of memory dies 710A . . . 710N, 720A . . . 720N may be vertically stacked on top of each other.

Logic dies 810, 910 and hosts 820, 920 (e.g., CPUs, GPUs, SoCs) are interconnected through respective interposers 830, 930, which are further located on top of and connected to respective package substrates 840, 940. Logic dies 810, 910 may include circuitry, logic, and/or features to facilitate access to/from hybrid bonded memory stacks 802, 902. Each of memory dies 710A-710N, and 720A-720N may represent separate memory devices each having multiple layers of memory devices 120, 220 that may be accessed via respective memory channels. Each memory channel may further include multiple I/O signal paths.

It should be appreciated that as compared to typical memory dies of HBM stacks, which only include a single layer of memory devices, each of memory dies 710A, 710B, and each of memory dies 720A, 720B of hybrid bonded memory stacks 802, 902 include two layers of memory devices, thereby doubling the memory density at a given height. Moreover, due to the unique hybrid bonded structure of memory dies 710A, 710B, and 720A, 720B in accordance with embodiments of the present invention, the total memory density of the hybrid bonded memory stacks 802, 902 is doubled without sacrificing package height. In other words, hybrid bonded memory stacks 802, 902 provide for double the total memory density of conventional HBM stacks, while being substantially similar in package height as conventional HBM packages.

The descriptions of the various embodiments of the present invention have been presented for purposes of illustration but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein.

In addition, any specified material or any specified dimension of any structure described herein is by way of example only. Furthermore, as will be understood by those skilled in the art, the structures described herein may be made or used in the same way regardless of their position and orientation. Accordingly, it is to be understood that terms and phrases such as, for instance, “side”, “over”, “perpendicular”, “tilted”, etc., as used herein refer to relative location and orientation of various portions of the structures with respect to one another, and are not intended to suggest that any particular absolute orientation with respect to external objects is necessary or required.

The foregoing specification also describes processing steps. While some of the steps may be in an ordered sequence, others may in different embodiments from the order that they were detailed in the foregoing specification. The ordering of steps when it occurs is explicitly expressed, for instance, by such adjectives as, “ordered”, “before”, “after”, “following”, and others with similar meaning.

Benefits, other advantages, and solutions to problems have been described above with regard to specific embodiments. However, the benefits, advantages, solutions to problems, and any element(s) that may cause any benefit, advantage, or solution to occur or become more pronounced are not to be construed as a critical, required, or essential feature, or element, of any or all the claims.

Many modifications and variations of the present invention are possible in light of the above teachings, and could be apparent for those skilled in the art.

What is claimed is:

1. A memory device, comprising:
a stack of memory dies, wherein each memory die in the stack of memory dies includes two or more layers of memory devices.

2. The memory device of claim 1, wherein a first layer of memory devices and a second layer of memory devices included in each memory die in the stack of memory dies are the same.

3. The memory device of claim 1, wherein a first layer of memory devices and a second layer of memory devices included in each memory die in the stack of memory dies are different.

4. The memory device of claim 1, wherein each memory die in the stack of memory dies is formed by hybrid bonding of a first BEOL interconnect structure of a first memory die to a second BEOL interconnect structure of a second memory die.

5. The memory device of claim 1, wherein for each memory die in the stack of memory dies:
a first layer of memory devices is located below a semiconductor substrate;
a second layer of memory devices is located between the first layer of memory devices and a back-end-of-the-line (BEOL) interconnect structure; and
a backside interconnect structure is located below the second layer of memory devices.

6. The memory device of claim 5, wherein the BEOL interconnect structure is formed by hybrid bonding a first BEOL interconnect structure of a first memory die and a second BEOL interconnect structure of a second memory die.

7. The memory device of claim 5, wherein a metal layer of the BEOL interconnect structure having metal lines with a largest pitch is located in the middle of the BEOL interconnect structure.

8. The memory device of claim 5, wherein each memory die further includes one or more through-silicon-vias (TSVs), the one or more TSVs formed within, and extending through, the semiconductor substrate, the first layer of memory devices, the BEOL interconnect structure, the second layer of memory devices, and the backside interconnect structure.

9. The memory device of claim 5, wherein each memory die further includes one or more through-silicon-vias (TSVs), the one or more TSVs formed within, and extending through, the semiconductor substrate, the first layer of memory devices, and a top portion of the BEOL interconnect structure.

10. The memory device of claim 5, wherein each memory die in the stack of memory dies further includes one or more deep trench capacitors formed within the semiconductor substrate.

11. The memory device of claim 1, wherein the stack of memory dies are vertically stacked on top of a logic die.

12. The memory device of claim 11, wherein the logic die is connected to at least one of an interposer or a package substrate.

13. A memory die, comprising:
a first layer of memory devices formed on top of a semiconductor substrate;
a back-end-of-the-line (BEOL) interconnect structure formed on top of the first layer of memory devices;
a second layer of memory devices formed on top of the BEOL interconnect structure; and
a backside interconnect structure formed on top of the second layer of memory devices.

14. The memory die of claim 13, further comprising:
one or more through-silicon-vias (TSVs) formed within, and extending through, the semiconductor substrate, the first layer of memory devices, the BEOL interconnect structure, the second layer of memory devices, and the backside interconnect structure.

15. The memory die of claim 13, further comprising:
one or more through-silicon-vias (TSVs) formed within, and extending through, the semiconductor substrate, the first layer of memory devices, and a bottom portion of the BEOL interconnect structure.

16. A method of forming a memory device, comprising:
forming a first memory wafer structure, the first memory wafer structure including a first semiconductor substrate, a first layer of memory devices formed on top of the first semiconductor structure, and a first back-end-of-the-line (BEOL) interconnect structure formed on top of the first layer of memory devices;
forming a second memory wafer structure, the second memory wafer structure including a second semiconductor substrate, a second layer of memory devices formed on top of the second semiconductor structure, and a second BEOL interconnect structure formed on top of the second layer of memory devices;
combining the first memory wafer structure and the second memory wafer structure to form a combined memory wafer structure by flipping over the second memory wafer structure and hybrid bonding the second BEOL interconnect structure of the second memory wafer structure to the first BEOL interconnect structure of the first memory wafer structure;
removing the second semiconductor substrate from the combined memory wafer structure to reveal the second layer of memory devices;
forming a backside interconnect structure on top of the second layer of memory devices; and
performing wafer dicing to separate respective memory dies from the combined memory wafer structure,
wherein each respective memory dies includes two layers of memory devices.

17. The method of claim 16, further comprising:
forming, prior to combining the first memory wafer structure to the second memory wafer structure, one or more deep trench capacitors within the first semiconductor substrate of the first memory wafer structure.

18. The method of claim 16, further comprising:
forming, prior to combining the first memory wafer structure and the second memory wafer structure, one or more through-silicon-vias (TSVs) within the first semiconductor substrate of the first memory wafer structure.

19. The method of claim 16, further comprising:
forming, after combining the first memory wafer structure and the second memory wafer structure, one or more through-silicon-vias (TSVs) within, and extending through, the backside interconnect structure, the second layer of memory devices, the second BEOL interconnect structure, the first BEOL interconnect structure, the first layer of memory devices, and the first semiconductor substrate.

20. The method of claim 16, further comprising:
vertically stacking two or more respective memory dies separated from the combined memory structure on top of a logic die.
